(19) United States
(12) Patent Application Publication
(10) Pub. No.: US 2016/0308039 A1
(43) Pub. Date: Oct. 20, 2016

(54) NITRIDE SEMICONDUCTOR DEVICE AND A PROCESS TO FORM THE SAME

(71) Applicant: SUMITOMO ELECTRIC INDUSTRIES, LTD., Osaka (JP)

(72) Inventor: Eiji SAITO, Yokohama-Shi (JP)

(73) Assignee: SUMITOMO ELECTRIC INDUSTRIES, LTD., Osaka (JP)

(21) Appl. No.: 15/130,124

(22) Filed: Apr. 15, 2016

(30) Foreign Application Priority Data
Apr. 17, 2015 (JP) 2015-085162

(51) Int. Cl. H01L 29/778; H01L 29/66; H01L 29/20; H01L 21/02

(52) U.S. Cl. CPC H01L 29/7787; H01L 21/0254; H01L 21/0262; H01L 21/02277; H01L 29/66462; H01L 29/2003

(57) ABSTRACT

A nitride semiconductor device and a process to form the same are disclosed. The semiconductor device includes a GaN channel layer, a barrier layer and a cap layer, where they are sequentially grown on a semiconductor substrate. The cap layer has, when the barrier layer is made of InAlN, a surface roughness shorter than 0.4 nm and a carbon concentration greater than 1019 cm−3. The process grows the GaN cap layer by changing the carrier gas for the group III source gas from hydrogen (H) to nitrogen (N) and, when the barrier layer is made of InAlN, at a temperature preferably 600 to 1000° C. lower than the growth temperature of the GaN channel layer.

### BACKGROUND OF THE INVENTION

1. Field of the Invention

The present invention relates to a nitride semiconductor device and a process to form the same.

2. Related Prior Arts

A high electron mobility transistor (HEMT) primarily formed by nitride semiconductor materials, typically, gallium nitride (GaN) has been practically applied in various modules and apparatuses. A process to form a nitride HEMT sequentially grows, on a semi-insulating substrate, a buffer layer, a GaN channel layer, a barrier layer, and a cap layer; and electrodes of a source, a drain, and a gate are subsequently formed in respective locations on thus grown semiconductor layers. The HEMT thus formed provides a two-dimensional electron gas (2DEG) in the GaN channel layer at an interface against the barrier layer.

However, a HEMT made of nitride semiconductor materials leaves subjects, one of which is an increased gate leak current and another is a current collapsing. The current collapsing is a phenomenon where a drain current just after a large negative gate bias decreases compared with a drain current enough after the large negative gate bias, namely, a steady gate bias. The present invention of a nitride HEMT and a process to from the nitride HEMT may effectively solve the two subjects above mentioned.

### SUMMARY OF THE INVENTION

One aspect of the present invention relates to a process to form a semiconductor device that includes a semiconductor stack having a channel layer, and a cap layer made of gallium nitride (GaN) provided on the semiconductor stack. The process of the present application includes steps of: (1) growing the semiconductor stack on a semiconductor substrate by a metal organic chemical vapor deposition (MOCVD) technique as supplying hydrogen (H) as a carrier gas; and (2) growing the cap layer made of gallium nitride (GaN) by the MOCVD technique as supplying nitrogen (N) as the carrier gas.

In an embodiment, the step of growing the semiconductor stack may include a step of growing a gallium nitride (GaN) layer as the channel by supplying source gasses for nitrogen (N) and gallium (Ga), respectively, with a first V/III ratio as flowing the hydrogen of the carrier gas, and the step of growing the cap layer may include a step of supplying the source gasses with a second V/III ratio smaller than a half of the first V/III ratio.

Another aspect of the present application relates to a semiconductor device, in particular, relates to a nitride semiconductor device that includes a semiconductor stack provided on a semiconductor substrate and a cap layer provided on the semiconductor stack and made of gallium nitride (GaN). A feature of the semiconductor device of the present embodiment is that the cap layer has a carbon concentration [C] higher than 1×10¹⁹ cm−3. Or, another feature of the semiconductor device is that the cap layer in a top surface thereof has a surface roughness, in a unit of root mean square (RMS) value, shorter than 0.4 nm measured by the atomic force microscope.

### BRIEF DESCRIPTION OF THE DRAWINGS

The foregoing and other purposes, aspects and advantages will be better understood from the following detailed description of a preferred embodiment of the invention with reference to the drawings, in which:

FIG. 1 shows a cross section of an epitaxial substrate according to an embodiment of the present invention;

FIG. 2 shows a cross section of a high electron mobility transistor (HEMT) formed on the epitaxial substrate shown in FIG. 1;

FIG. 3 shows a flow chart of a process of forming the HEMT shown in FIG. 2;

FIG. 4 shows a behavior of growth temperatures of forming the epitaxial substrate shown in FIG. 1;

FIG. 5 shows a relation of current collapsing against the carbon concentration of a GaN cap layer grown at various temperatures; and

FIG. 6 shows a relation of gate leak currents against averages of square pitches of undulations observable by an atomic force microscope (AFC) in a top surface of the GaN cap layer grown at various temperatures.

### DESCRIPTION OF EMBODIMENT

Next, some examples according to the present invention will be described as referring to drawings. In the description of the drawings, numerals or symbols same with or similar to each other will refer to elements same with or similar to each other without duplicating explanations.

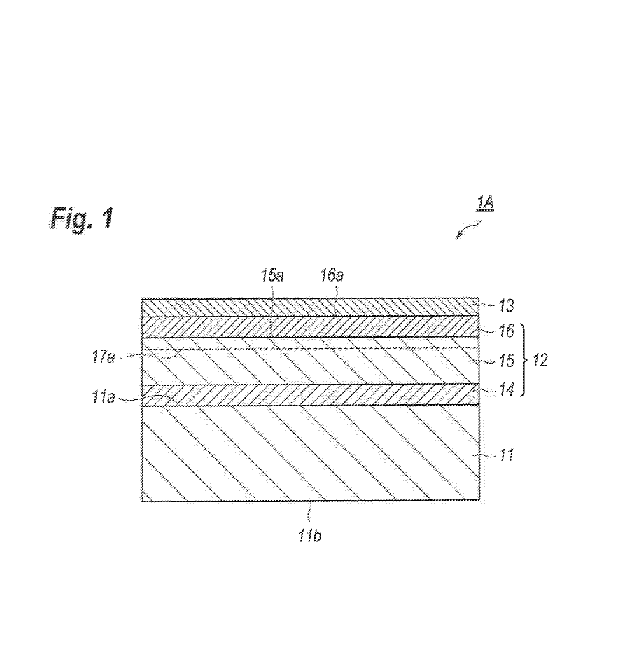

FIG. 1 shows a cross section an epitaxial substrate 1A according to an embodiment of the present embodiment. The epitaxial substrate shown in FIG. 1A, which is applicable to a high electron mobility transistor (HEMT), includes a semiconductor substrate 11, a semiconductor stack 12, and a cap layer 13. The semiconductor stack 12 includes a buffer layer 14, a GaN layer 14, and a barrier layer 16.

The semiconductor stack 11 may be made of, for instance, silicon carbide (SiC), silicon (Si), and/or sapphire (Al₂O₃). The present embodiment provides the semiconductor substrate of SiC. The semiconductor substrate 11 provides a primary surface 11a, on which the semiconductor stack 12 is epitaxially grown, and a back surface 11b.

The buffer layer 14, which is grown on the primary surface 11a of the semiconductor substrate 11, may enhance crystal quality of semiconductor layer grown thereon. That is, when the semiconductor layers grown thereon have lattice constants different from that of the semiconductor substrate 11, the buffer layer 14 may partly compensate the difference in the lattice constants. The present embodiment provides the buffer layer 14 made of undoped aluminum nitride (AlN) with a thickness of about 50 nm.

A gallium nitride (GaN) layer 15, which is epitaxially grown on the buffer layer 14, may primarily include nitride semiconductors, where the present embodiment provides the undoped GaN with a thickness of 200 to 1200 nm, preferably around 1000 nm. The GaN layer 15 may form a two-dimensional electron gas (2DEG) in an interface against a barrier layer 16, when the semiconductor stack 12 and the semiconductor substrate 11 are formed into a HEMT. The 2DEG operates as a channel 17 extending from a top surface 15a of the GaN layer 15; accordingly, the GaN layer 15 is often called as a channel layer.

The barrier layer 16, which is also epitaxially grown on the GaN layer 15 with a thickness of 5 to 30 nm, preferably 10 nm, may be made of a semiconductor material or materials having the electron affinity greater than that of the channel 17. For instance, the barrier layer 16 may be made of aluminum gallium nitride (AlGaN) with an aluminum (Al) composition of 0.2 to 0.45, or indium aluminum nitride (InAlN) with an indium (In) composition of 0.1 to 0.25. The barrier layer 15 in a top surface 16a thereof may have a roughness shorter than 0.4 nm in a term of the root mean square (RMS) measured by the atomic force microscope (AMF). The roughness in the RMS unit means an average of square pitches of undulations observable in a surface of a material by the AMF. The cap layer 13, which is also epitaxially grown on the barrier layer 16 to protect the semiconductor stack 12, may be made of undoped GaN with a thickness of 1 to 7 nm, preferably 5 nm.

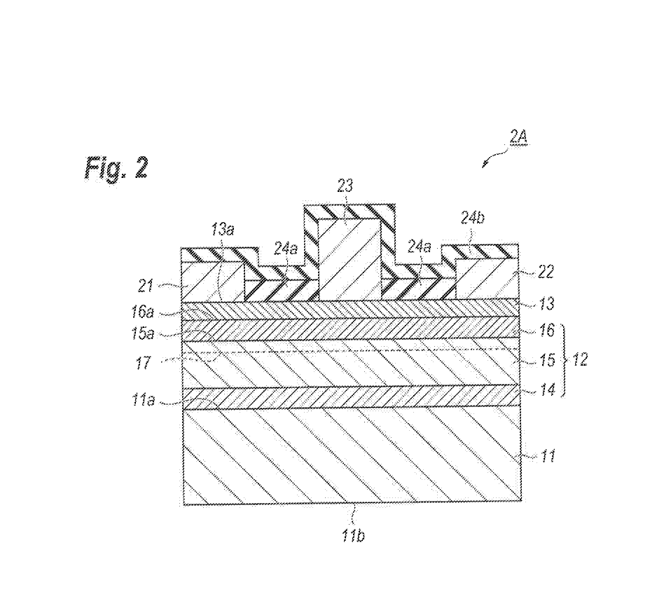

FIG. 2 shows a cross section of a HEMT 2A formed from the epitaxial substrate 1A shown in FIG. 1. The HEMT 2A provides, on the semiconductor substrate 11, the semiconductor stack 12, the cap layer 13, a source electrode 21, a drain electrode 22, a gate electrode 23, and passivation films, 24a and 24b. The semiconductor substrate 11, the semiconductor stack 12, and the cap layer 13 have arrangements same with those described above except for those explained below.

The source and drain electrodes, 21 and 22, which are provided on a top surface 13a of the cap layer 13 and show ohmic characteristics, may be made of stacked titanium (Ti) and aluminum (Al), where Ti layer is in contact to the cap layer 13. The source and drain electrodes, 21 and 22, may further provide another titanium (Ti) layer on a top of Al layer, that is, Al layer may be sandwiched between Ti layers. Although the HEMT 2A shown in FIG. 2 provides the source and drain electrodes, 21 and 22, in contact to the cap layer 13, a HEMT may provide the source and drain electrodes, 21 and 22, in directly contact to the barrier layer 16 by partly removing the cap layer 13.

The gate electrode 23, which is provided on the cap layer 13 between the source and drain electrodes, 21 and 22, may be made of stacked nickel (Ni) and gold (Au). The passivation film 24a may cover the top surface of the cap layer 13 between the source electrode 21 and the gate electrode 23, and between the gate electrode 23 and the drain electrode 22. The other passivation film 23b may cover the source, drain, and gate electrodes, 21 to 23, respectively. These passivation films, 24a and 24b, may be made of silicon nitride (SiN).

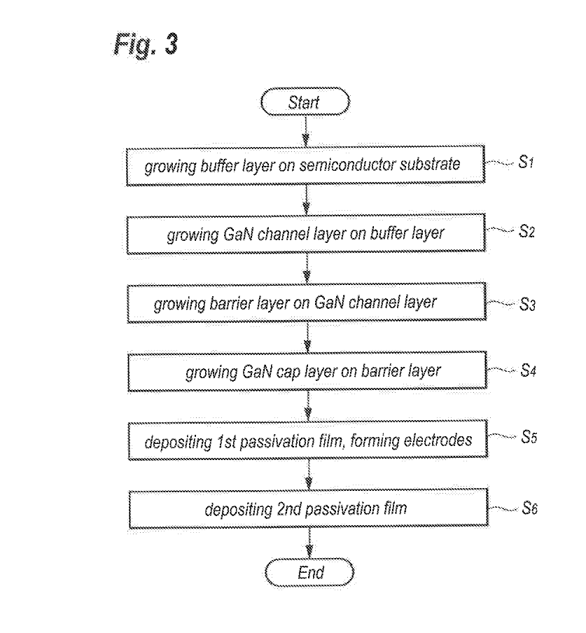

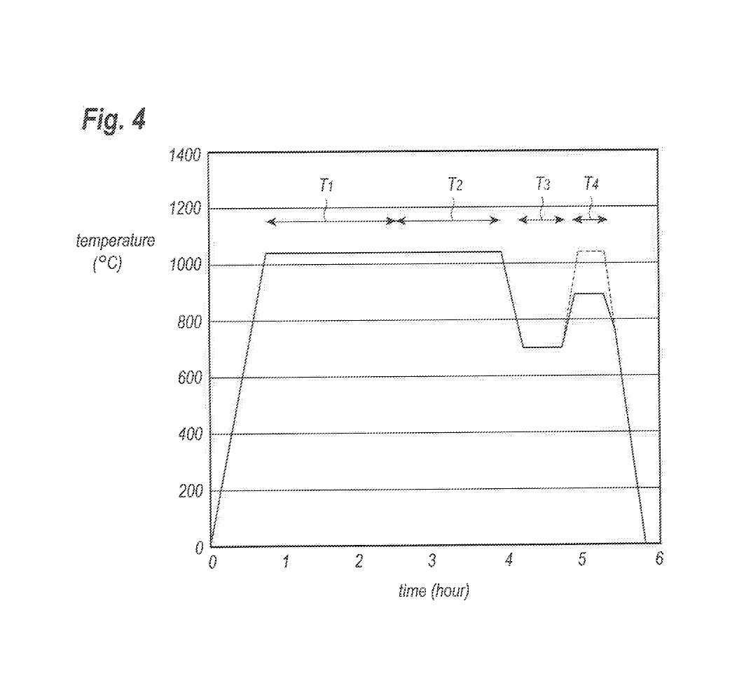

Next, a process for preparing the epitaxial substrate 1A and for making the HEMT 2A on the epitaxial substrate 1A will be described. FIG. 3 shows a flow chart of the process, and FIG. 4 shows a behavior of a temperature of the epitaxial substrate 1A during the process, where the vertical axis shows the growth temperature of the semiconductor layers, and the horizontal axis corresponds to a process time. The process according to the present embodiment grows the buffer layer 14, the GaN layer 15, the barrier layer 16, to and the cap layer 13 by the metal organic chemical vapor deposition (MOCVD) technique.

The process first sets, at step S₁, the temperature of the semiconductor substrate 11 in a preset temperature, then, supplies source gasses of tri-methyl-aluminum (TMA) for the group III element and ammonia for the group V element each accompanying with carrier gases which may be, for instance, hydrogen in the present embodiment. Thus, the process may grow the buffer layer 14 made of AlN on the semiconductor substrate 11. The step S₁ keeps the semiconductor substrate 11 in a temperature thereof higher than 1000° C., for instance, 1050° C. during the period T₁ in FIG. 4.

Next, the process changes the source gas for the group III element from the TMA to tri-methyl-gallium (TMG) accompanying with the carrier gas of the hydrogen. Thus, the GaN layer 15 may be epitaxially grown on the buffer layer 14 at step S₂. During the step S₂, the process keep the semiconductor substrate 11 in the temperature thereof higher than 1000° C., preferably 1050° C.; that is, the step S₂ keeps the semiconductor substrate 11 in the temperature thereof same with that during the previous step S₁ for growing the buffer layer 14 for a period T₂ in FIG. 4.

Then, at step S₃, the process changes the source gas for the group III element from the TMG to a mixture of TMA and tri-methyl-indium (TMI) as keeping the source gas for the group V element to be ammonia accompanying with the carrier gas of hydrogen. Thus, the process may epitaxially grow the barrier layer made of InAlN on the GaN layer 15. At step S₃, the process keeps the semiconductor substrate 11 in the temperature thereof lower than that at step S₂. The present embodiment sets the temperature of the semiconductor substrate 11 to be 700° C. during a period T₃. Accordingly, a step to lower the temperature of the semiconductor substrate 11 may be done before step S₃. During the period T₃, the process keeps a pressure within a MOCVD chamber to be 50 Torr (6.7 kPa).

Next, the TMG as the source gas for the group III element with a carrier gas and the ammonia as that for the group V element are supplied within a growth chamber at step S₄. The carrier gas is preferably changed from hydrogen (H) for growing aforementioned layers to nitrogen (N), which effectively reduces the etching of the semiconductor layers already grown by the hydrogen (H) and the GaN layer of the cap layer 13 may be formed with good quality and excellent flatness. The process of the embodiment, at step S₄, sets a growth temperature higher than or equal to 600° C. but lower than or equal to 1000° C., preferably between 650 to 750° C., during a period T₄ for the grown of the GaN layer 13 when the barrier layer 16 is made of InAlN. In FIG. 4, a broken line, denotes a conventional condition of a grown temperature of 1050° C. comparable to the present embodiment. When the barrier layer 16 is made of AlGaN, the growth temperature of the GaN cap layer 13 is set between 1000 to 1100° C., preferably equal to the growth temperature for the AlGaN barrier layer but the carrier gas for the group III element is changed to nitrogen (N) from hydrogen (H). During the period T₄ growing the GaN cap layer 13, the process keeps the pressure within the growth chamber to be, for instance, 50 Torr (6.7 kPa).

Also, the process sets a V/III ratio of the source gasses for growing the GaN cap layer 13 to be less than a half of the V/III ratio of the source gases for growing the GaN channel layer 15. For example, a ratio of the flow rate of the ammonia (NH₃) to the flow late of the TMG during the growth of the GaN channel layer 15 is set to be 500, but the ratio of the flow rates of the ammonia (NH3) and the TMG during the growth of the GaN cap layer 13 is set to be 200.

Thus, the epitaxial substrate 1A of the present embodiment is prepared. The process subsequently deposits the first passivation film 24a on a whole surface of the epitaxial substrate 1A, forms openings for electrodes, and fills thus formed openings with metals for the source electrode 21, the drain electrode 22, and the gate electrode 23, at step S₅. Finally, the process covers the electrodes, 21 to 23, and the first passivation film 24a with a second passivation film at step S₆. Thus, the HEMT 2A is completed.

Next, advantages of the epitaxial substrate 1A and the HEMT 2A formed on the epitaxial substrate 1A will be described. When a process grows a cap layer 13 at a temperature higher than 1000° C., for instance, a temperature same with the temperature for growing the buffer layer 14 and the GaN channel layer 15, the sublimation of atoms of the group III elements contained in the topmost layer in the semiconductor stack 12 exposed at the beginning of the growth, for instance, indium (In) in the barrier layer 16, may be accelerated and surface roughness of the semiconductor stack 12 increases, which is reflected on a surface of the grown layer, namely, the cap layer 13. A roughed surface of a semiconductor layer may form various leaking passes; accordingly, the leak current around the gate electrode 23 increases. On the other hand, when a cap layer 13 is grown at a relatively lower temperature, for instance, a temperature lower than 600° C., crystal quality thereof degrades and the gate leak current 23 resultantly increases.

Accordingly, the process of the present embodiment epitaxially grows the cap layer 13 at a temperature higher than 600° C. but lower than 1000° C. in order to suppress the sublimation of the group III atoms contained in the semiconductor stack 12 and the degradation of the surface roughness of the semiconductor stack 12. Thus, the process may reduce the leak current around the gate electrode 23.

In particular, when the barrier layer 16 is made of InAlN and epitaxially grown at a temperature comparable to the growth temperature of, for instance, AlGaN layer, which may be set to be about 1000° C., the sublimation of indium atoms from the InAlN layer is accelerated and the surface of the semiconductor layer grown on the InAlN layer becomes degraded. Even in such an arrangement of the semiconductor layers, the cap layer 13 of the present embodiment, which is grown at a relatively lower temperature, may suppress the sublimation of indium atoms which may keep the surface quality of the grown layer, the leak current around the gate electrode 23 may be effectively suppressed.

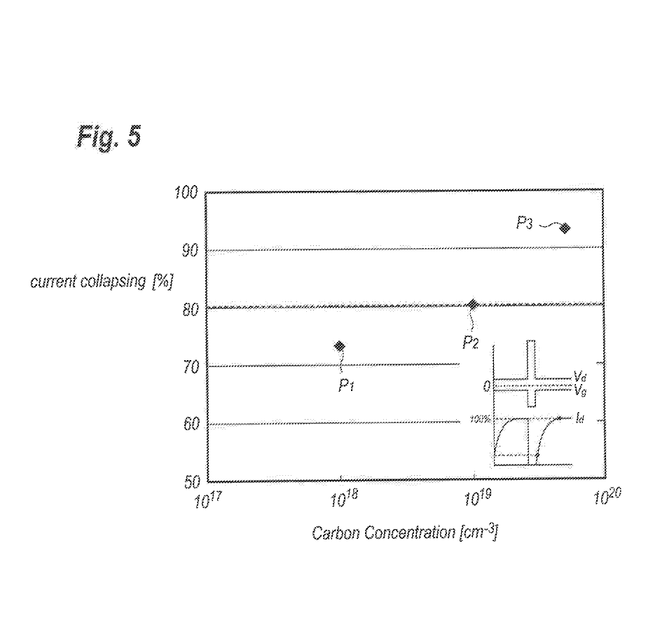

In a case where the growth temperature for the cap layer 13 is set lower than 1000° C., a carbon concentration [C] in the cap layer 13 thus grown increases compared with a case where the cap layer 13 is epitaxially grown at a temperature higher than 1000° C. An increased carbon concentration [C] may effectively compensate electron traps induced within the grown layer and resultantly decreases, what is called, the current collapsing. FIG. 5 shows a result of the reduction of the current collapsing, which was experimentally obtained. In FIG. 5, the vertical axis corresponds to the current collapsing in the unit of percentage (%), while, the horizontal axis denotes the carbon concentration [C] of the grown layer in the unit of [cm⁻³]. Results P₁ to P₃ correspond to cases where a cap layer 13 grown at a temperature of 1050° C., 1000° C., and 600° C., respectively. In the present specification, the current collapsing in the unit of percentage means as a ratio of a drain current measured just after an enough high reverse bias for the gate electrode against a drain current in a steady state, namely, a drain current measured enough after the reverse bias to the gate electrode. Because electron traps around the gate electrode, including the cap layer and the barrier layer, may be negatively charged by the reverse bias, which means that the gate electrode is equivalently biased in negative and an ordinary gate bias applied to the gate electrode is partly compensated, the drain current controlled by such a gate bias resultantly decreases during a period the electron traps releases the captured charges. The current collapsing and the carbon concentration were measured by proving a HEMT 2A as exposing the electrodes, 21 to 23, before the formation of the passivation film 24b.

As shown in FIG. 5, the current collapsing decreases as the carbon concentration [C] in the cap layer 13 increases. For instance, the current collapsing decreases less than 80% for the cap layer 13 grown at a temperature higher than 1000° C. Setting an acceptable range of the current collapsing to be 80%, the growth temperature for the cap layer 13 is preferably lower than 1000° C. A reason why the carbon concentration [C] reduces at growth temperatures lower than 1000° C. may be considered that a bond between a carbon and a group III atom in the source material for the group III element, namely the TMG, becomes hard to be dissociated. Accordingly, carbon atoms are captured within a grown layer accompanied with the group III elements.

Also, in the present embodiment, the semiconductor stack 12 provides the barrier layer 16 having the electron affinity greater than that of the channel 17, namely, the InAlN layer, or the AlGaN layer of the barrier layer 16 has the electron affinity greater than that of the GaN layer 15 beneath the barrier layer 16. Because the cap layer 13 grown on the barrier layer 16 is grown at relatively lower temperature and relatively slower growth rate, which may suppress the sublimation of the group III atoms from the barrier layer 16 and the degradation of the crystal quality of the grown layer, typically the surface roughness and the defects of the GaN cap layer 13, the current collapsing may be effectively improved.

The cap layer 13 of the present embodiment has the carbon concentration [C] greater than 10¹⁹ cm⁻³, which effectively improves the current collapsing as shown in FIG. 5. Carbon atoms are considered to fill or compensate the electron traps in the cap layer 13, and the current collapsing is resultantly decreased.

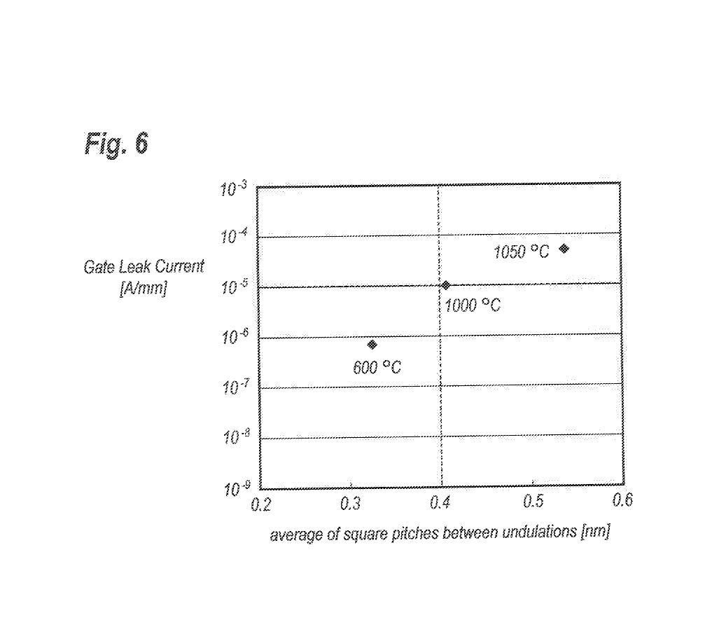

Also, the cap layer 13 of the present embodiment shows the surface roughness shorter than 0.4 nm in a term of the root mean square (RMS) measured by the atomic force microscope (AMF). FIG. 6 shows gate leak currents against the surface roughness in the teem of the RMS. When a cap layer 15 is grown at a temperature lower than 1000° C., the surface roughness, or the average of the square pitch of the surface undulation, becomes less than 0.4 nm in the unit of the RMS, and the leak current for the gate electrode 23 becomes smaller than 10 μA/mm.

The process according to the present embodiment changes the carrier gas for growing the cap layer 13 to nitrogen (N) from hydrogen (H) for growing the semiconductor stack 12. Because hydrogen shows a function to etch a semiconductor layer made of group III-V semiconductor materials, the change of the carrier gas from hydrogen to nitrogen may maintain the surface morphology and the surface flatness of the grown layer, which resultantly decreases the surface leak current.

The process of the embodiment also sets the flow rates of the source gasses for the GaN cap layer 13, namely the VIII ratio of the source gasses, to be less than that of the flow rates for the GaN channel layer 15. Such a smaller V/III ratio of the flow rates of the source gasses may decrease the growth rate of the semiconductor layer, suppress an extraordinary growth occasionally caused in a crystal growth at a temperature lower than 1000° C., and enhance the surface flatness. Then, the leak current around the gate electrode 23 may be reduced.

Also, the cap layer 13 has the surface roughness in the unit of RMS value shorter than 0.4 nm, which may reduce the surface leak current around the gate electrode 23, and the carbon concentration [C] greater than 1019 cm−3, which effectively fills or compensates the electron traps in the cap layer 13 and reduces the current collapsing.

While particular embodiments of the present invention have been described herein for purposes of illustration, many modifications and changes will become apparent to those skilled in the art. Accordingly, the appended claims are intended to encompass all such modifications and changes as fall within the true spirit and scope of this invention.

What is claimed is:

1. A process of forming a semiconductor device that includes a semiconductor stack having a channel layer and a cap layer made of gallium nitride (GaN) provided on the semiconductor stack, the process comprising steps of:
growing the semiconductor stack on a semiconductor substrate by a metal organic chemical vapor deposition (MOCVD) technique as supplying hydrogen (H) as a carrier gas; and
growing the cap layer on the semiconductor stack by the MOCVD technique as supplying nitrogen (N) as the carrier gas.

2. The process of claim 1,
wherein the step of growing the semiconductor stack includes a step of growing a gallium nitride (GaN) layer as the channel layer by supplying source gases for nitrogen (N) and for gallium (Ga), respectively, with a first V/III ratio as flowing the hydrogen of the carrier gas, and
wherein the step of growing the cap layer includes a step of supplying the source gasses with a second V/III ratio smaller less than a half of the first V/III ratio.

3. The process of claim 2,
wherein the step of growing the GaN layer of the channel layer and the GaN layer of the cap layer include the steps of supplying tri-methyl-gallium as the source gas for a group III element and ammonia (NH₃) as the source gas for a group V element.

4. The process of claim 1,
wherein the step of growing the semiconductor stack includes a step of growing indium aluminum nitride (InAlN) as a topmost layer thereof at a so temperature lower than a temperature for growing the channel layer, and the step of growing the cap layer includes a step of growing the GaN layer at a temperature lower than 1000° C. but higher than 600° C.

5. The process of claim 4,
wherein the step of growing the cap layer includes a step of growing the GaN layer at a temperature in a range from 650 to 750° C.

6. The process of claim 1,
wherein the step of growing the semiconductor stack includes a step of growing aluminum gallium nitride (AlGaN) as a topmost layer thereof at a temperature in a range of 1000 to 1100° C., and the step of growing the cap layer includes a step of growing the GaN layer at a temperature substantially equal to the temperature for growing the AlGaN layer.

7. A semiconductor device, comprising:
a semiconductor stack provided on a semiconductor substrate, the semiconductor stack including a channel layer made of gallium nitride (GaN); and
a cap layer made of GaN,
wherein the cap layer provides a carbon concentration [C] greater than or equal to 1×10¹⁹ cm⁻³.

8. The semiconductor device of claim 7
wherein the semiconductor stack includes a topmost layer having electron affinity greater than electron affinity of the GaN channel layer.

9. The semiconductor device of claim 8,
wherein the semiconductor stack includes an indium aluminum nitride (InAlN) as a topmost layer thereof.

10. The semiconductor device of claim 8,
wherein the semiconductor stack includes an aluminum gallium nitride (AlGaN) as a topmost layer thereof.

11. The semiconductor device of claim 7,
wherein the cap layer in a top surface thereof has a roughness less than 0.4 nm in a root mean square (RMS) value measured by an atomic force microscope.

12. A semiconductor device, comprising:
a semiconductor stack provided on a semiconductor substrate, the semiconductor stack including a channel layer made of gallium nitride (GaN); and
a cap layer made of GaN,
wherein the cap layer in a top surface thereof has a roughness less than 0.4 nm in a root mean square (RMS) value measured by an atomic force microscope.

13. The semiconductor device of claim 12,
wherein the semiconductor stack includes a topmost layer having electron affinity greater than electron affinity of the channel layer.
